(19) United States
(12) Patent Application Publication
(10) Pub. No.: US 2024/0404917 A1
(43) Pub. Date: Dec. 5, 2024

(54) SELF-ALIGNED VIA PATTERNING FOR BACKSIDE INTERCONNECTS

(71) Applicant: Intel Corporation, Santa Clara, CA (US)

(72) Inventors: Sikandar Abbas, Forest Grove, OR (US); Chanaka Munasinghe, Portland, OR (US); Leonard Guler, Hillsboro, OR (US); Reza Bayati, Portland, OR (US); Madeleine Stolt, Beaverton, OR (US); Makram Abd El Qader, Hillsboro, OR (US); Pratik Patel, Portland, OR (US); Anindya Dasgupta, Portland, OR (US)

(73) Assignee: Intel Corporation, Santa Clara, CA (US)

(21) Appl. No.: 18/204,864

(22) Filed: Jun. 1, 2023

(51) Int. Cl. H01L 23/48; H01L 21/768; H01L 23/528

(52) U.S. Cl. CPC H01L 23/481; H01L 21/76898; H01L 23/528; H01L 29/0673; H01L 29/42392; H01L 29/775

(57) ABSTRACT

Devices, transistor structures, systems, and techniques are described herein related to coupling backside and frontside metallization layers that are on opposite sides of a device layer. A device includes a transistor having semiconductor structures extending between a source and a drain, and a gate between the source and drain, a bridge via extending between a frontside metallization over the transistor and a backside metallization below the transistor, and a thin insulative liner between the bridge via and components of the transistor.

### BACKGROUND

Higher performance, lower cost, increased miniaturization, and greater density of integrated circuits (ICs) are ongoing goals of the electronics industry. Backside interconnects are an important aspect for advancement in the semiconductor industry towards these goals. Backside interconnects, for example, can provide power from the backside of the transistor device. This offers advantages including a lower resistance path to power the transistor devices, opening space on the frontside of the transistor device layout, and others. This, in turn, improves transistor device performance metrics both in per power terms and per area terms.

A key enabler for backside interconnects is the power vias that bridge the frontside and the backside interconnects. Currently, patterning for the power vias requires advanced lithography steps that increase process complexity and cost. Furthermore, current patterning schemes are susceptible to marginality and variation issues that adversely impact yield and performance. Such power via patterning is difficult and may not be extendible to future process nodes where device density increases and the space for patterning will be significantly smaller. The techniques and structures discussed herein offer improved power vias for backside interconnects. Such improvements may become critical as the desire to deploy advanced transistor structures becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming a bridge via to extend between metallization layers on opposite sides of a transistor layer and a thin insulative liner for the bridge via;

FIGS. 2, 3, 4, 5, 6, 7, 8, 9, 10, 11, 12, and 13 are cross-sectional views of transistor structures evolving as the methods of FIG. 1 are practiced to form a bridge via adjacent to gate electrodes of the transistor structures;

FIGS. 14, 15, 16, 17, 18, 19, 20, 21, 22, 23, and 24 are cross-sectional views of transistor structures evolving as the methods of FIG. 1 are practiced to form a bridge via adjacent to source and drain contacts of the transistor structures;

FIG. 25 illustrates exemplary systems employing transistor structures having a bridge via within a thin insulative liner; and

FIG. 26 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, transistor structures, integrated circuit dies, apparatuses, systems, and techniques are described herein related to vias extending from frontside metallization layers over a transistor device to backside metallization layers under transistor device, which have improved alignment, reduced insulative liner thickness, and reduced spacing requirements.

As discussed, backside interconnects or backside metallization layers are an important aspect for advancement in the semiconductor industry. Such backside interconnects are vertically opposite from frontside metallization layers with respect to a device layer therebetween. For example, the frontside metallization layers are over a device layer including transistors and the backside metallization layers are under the transistors. After fabrication of frontside metallization layers, the backside metallization layers may be formed by attaching a wafer to a carrier, removing the substrate over which the transistors and frontside metallization layers were formed, forming the backside metallization layers, and removing the carrier. Such backside metallization layers and frontside metallization layers may be interconnected by metal vias that vertically extend across or span the transistors. The metal vias may be characterized as vias, deep vias, bridge vis, across-transistor vias, interconnect vias, or the like. In some contexts, the vias may be characterized as power vias as the deliver power from the backside metallization layers to the transistor devices. However, the metal vias may deliver signal routing, ground routing, or provide any suitable interconnection.

Notably, the vias bridge the frontside and the backside metallization layers interconnects. Currently, patterning for the vias requires multiple advanced lithography steps. The structures and techniques discussed herein provide for a self-aligned via patterning process for the vias that enable improved backside interconnection by addressing disadvantages of process complexity, requirements for large layout space, non-optimal transistor performance, and others. Notably, the bridge vias are self-aligned to eliminate lithography operations, reduce process variations, and require thinner spacers or insulative liner layers, which allows increased transistor density and improved transistor performance. Such self-aligned via pattering operations and the resultant structures are attained by material selection, etch and polish selectivity, and patterning sequencing.

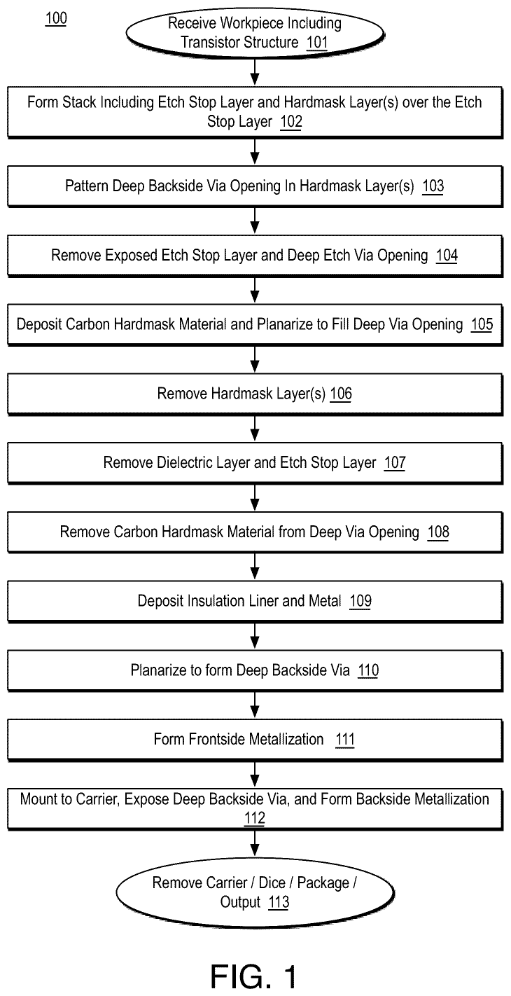

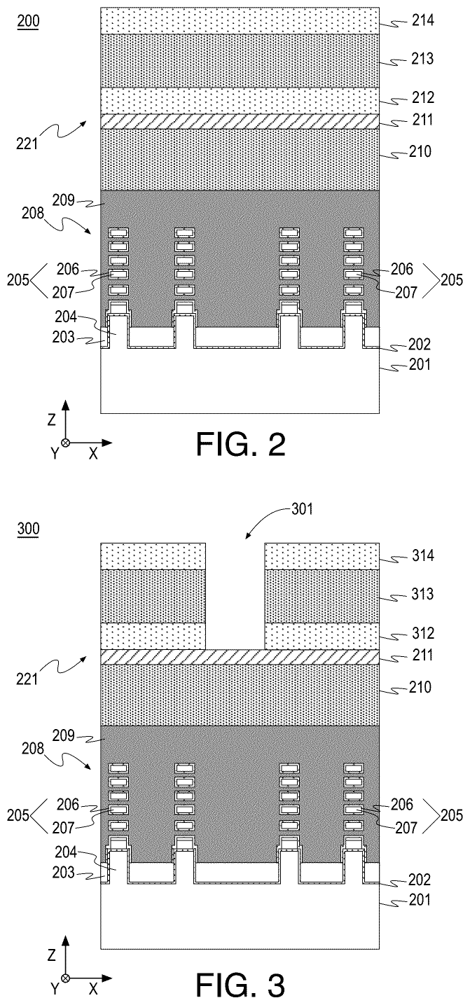

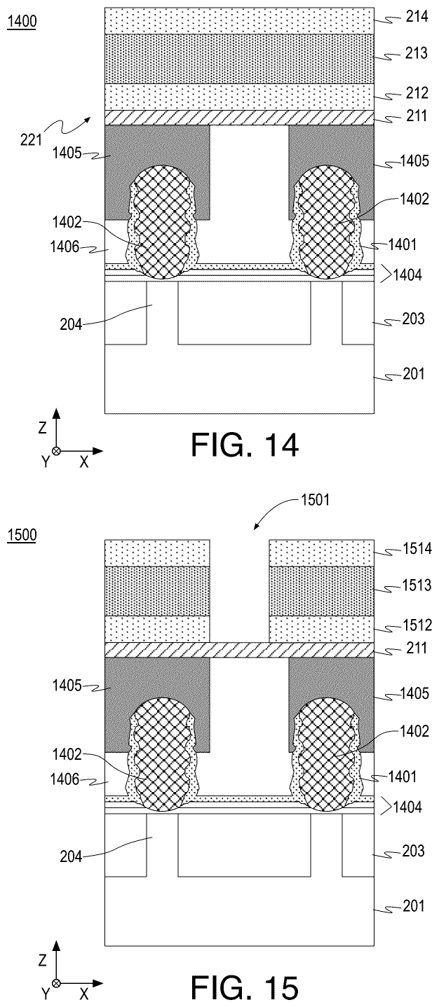

FIG. 1 is a flow diagram illustrating methods 100 for forming a bridge via to extend between metallization layers on opposite sides of a transistor layer and a thin insulative liner for the bridge via, arranged in accordance with at least some implementations of the present disclosure. FIGS. 2, 3, 4, 5, 6, 7, 8, 9, 10, 11, 12, and 13 are cross-sectional views of transistor structures evolving as methods 100 are practiced to form a bridge via adjacent to gate electrodes of the transistor structures, arranged in accordance with some embodiments of the disclosure. For example, the bridge vias may be formed within a gate track of the transistor structures. FIGS. 14, 15, 16, 17, 18, 19, 20, 21, 22, 23, and 24 are cross-sectional views of transistor structures evolving as methods 100 are practiced to form a bridge via adjacent to source and drain contacts of the transistor structures, arranged in accordance with some embodiments of the disclosure. For example, the bridge vias may be formed within a source/drain contact track of the transistor structures. Although illustrated with respect to formation within gate tracks and source/drain contact tracks of the transistor structures, the bridge vias may be formed at any suitable location. Furthermore, methods 100 may be used to form the bridge vias in the gate tracks and source/drain contact tracks simultaneously.

Methods 100 begin at input operation 101, where a workpiece including at least a partially formed transistor structure is received for processing. For example, a substrate may be received for processing such that a transistor or transistor structure has been fabricated over the substrate. In some embodiments, the transistor includes one or more semiconductor structures extending between a source structure and a drain structure. A gate structure (e.g., a gate dielectric and a gate electrode) is between the source and drain structures such that the gate structure is adjacent to channel regions of the one or more semiconductor structures. Furthermore, the source structure and the drain structure may be contacted by source and drain contacts, respectively. For example, the transistor may be part of a transistor layer or device layer formed over the substrate.

Processing continues at operation 102, where a stack of layers is formed over the transistor structures. The stack of layers includes an etch stop layer over the transistor layer and one or more hardmask layers over the etch stop layer. Notably, the hardmask layer(s) provide a resistant or durable material to transfer a pattern formed in the hardmask layer(s) via etch processing to underlying layers of the transistor structures. Furthermore, one or more of the hardmask layer(s) have an etch selectively with respect to the etch stop layer. In some embodiments, the etch stop layer is aluminum oxide (e.g., includes aluminum and oxygen). In some embodiments, the hardmask layer is silicon nitride (e.g., includes silicon and nitrogen). In some embodiments, the hardmask layer is silicon nitride, which is between silicon oxide layers (e.g., layers including silicon and oxygen). For example, the material stack formed at operation 102 may be an aluminum oxide etch stop layer (e.g., substantially pure or pure aluminum oxide) formed on the received workpiece, a silicon oxide layer (e.g., substantially pure or pure silicon oxide) formed on the aluminum oxide etch stop layer, a silicon nitride hardmask layer (e.g., substantially pure or pure silicon nitride) formed on the first silicon oxide layer, and a silicon oxide layer (e.g., substantially pure or pure silicon oxide) formed on the silicon nitride hardmask layer.

Processing continues at operation 103, where an opening that is to pattern a deep backside via is patterned in the hardmask layer(s). The opening may be formed using any suitable technique or techniques such as patterning an opening in a resist layer over the discussed material stack and transferring the opening to the hardmask via a hardmask etch. In some embodiments, the opening is patterned into each of the layers over the etch stop layer but not the etch stop layer itself. For example, continuing with the above material stack example, the opening may be patterned into the silicon oxide layer on the aluminum oxide, the silicon nitride hardmask layer on the first silicon oxide layer, and the second silicon oxide layer on the silicon nitride hardmask layer, but not the aluminum oxide layer.

Processing continues at operation 104, where the exposed portion of the etch stop layer (e.g., below the opening) is removed and a deep etch is performed to form a via opening that extends vertically across the discussed transistor layer and, optionally, into the substrate on which the transistor layer was formed. Notably, the deep etch extends the via opening to a depth at which an eventual metal via may be accessed from the backside of the transistor layer. In some embodiments, the exposed portion of the etch stop layer is removed using a dilute hydrofluoric acid (DHF) etch. In some embodiments, the deep etch is a timed anisotropic etch that etches selective to the silicon nitride hardmask layer (e.g., etches silicon nitride more slowly relative to the underlying materials). In some embodiments, the etch is timed to stop at a predetermined depth in the substrate.

Processing continues at operation 105, where a hardmask material such as a carbon hardmask material is deposited in the deep via opening and planarized to fill or plug the deep via opening. Although discussed with respect to a carbon hardmask material, any material having etch selectively relative to the hardmask layer (e.g., silicon nitride), the etch stop layer (e.g., aluminum oxide) and other layers if deployed (e.g., silicon oxide) may be used. The hardmask material may be deposited using any suitable technique or techniques such as plasma-enhanced chemical vapor deposition (PECVD). Following the hardmask material deposition, the chemical mechanical polishing (CMP) techniques may be used to remove the hardmask material over the via opening.

Processing continues at operation 106, where the hardmask material layer(s) are removed. For example, the silicon nitride hardmask layer may be removed using any suitable technique or techniques such as anisotropic etch techniques (e.g., an anisotropic silicon nitride etch). Such processing leaves a protrusion of the carbon hardmask material plug over the via opening. Processing continues at operation 107, where an underlying dielectric layer (if applicable) and the etch stop layer are removed. For example, the silicon oxide layer and the aluminum oxide etch stop layer may be removed using wet etch techniques such as a DHF etch. Again, such processing leaves a protrusion of the carbon hardmask material plug over the via opening.

Processing continues at operation 108, where the carbon hardmask material deposited at operation 105 is removed to expose the deep via opening formed at operation 104, with the material stack applied at operation 102 removed. That is, such processing provides a deep via opening in the original received workpiece. Such processing provides the deep via opening with a single lithography operation (discussed at operation 103) with the remaining operations being self-aligned to the single lithography operation. This process flow offers the advantage of reduced complexity and reduction in process variation that can result from addition lithography operations.

Processing continues at operation 109, where an insulative liner material is deposited into the deep via opening, such that it lines the sidewalls of the opening, and a metal is formed within the opening and on the insulative liner material. The insulative liner material may be deposited using any suitable conformal deposition techniques such as chemical vapor deposition (CVD), atomic layer deposition (ALD), or others. In some embodiments, the insulative liner material is silicon nitride (e.g., includes silicon and nitrogen). In some embodiments, the insulative liner material is substantially pure or pure silicon nitride. The metal formed within the opening may be any suitable metal. In some embodiments, the metal is tungsten. However other metals such as copper, aluminum, or others may be used.

Processing continues at operation 110, where planarization is performed to remove bulk metal and insulative liner material from over the deep via opening. Such processing provides an insulative liner material on sidewalls of the opening and metal via (e.g., a metal plug) within the insulative liner material such that the insulative liner material is also on a sidewall of the metal via. Due to the discussed processing, the insulative liner material may be thin relative to the size (e.g., width) of the metal via. Notably, by having the insulative liner material and the metal via self-aligned to the via opening formed using a single lithography operation, the insulative liner material may be scaled to a very thin lateral width (or lateral thickness). For example, in processing where a second lithography operation is aligned to the lithography operation used to form the via opening while the via opening is filled with insulative material, a wide process margin (e.g., 12+ nm) is needed to reliably land the metal via opening within the insulative material. Therefore, for a 20 nm wide via, 44+ nm of space is needed to reliably land the via, which necessitates an insulative material width of about 12 nm.

By self-aligning the metal via and the insulative liner material as discussed herein, a much thinner insulative liner material may be deployed. In some embodiments, the lateral width (or lateral thickness) of the insulative liner material is less than 12 nm. In some embodiments, the lateral width (or lateral thickness) of the insulative liner material is less than 10 nm. In some embodiments, the lateral width (or lateral thickness) of the insulative liner material is less than 8 nm. In some embodiments, the lateral width (or lateral thickness) of the insulative liner material is less than 5 nm. In some embodiments, the lateral width (or lateral thickness) of the insulative liner material is less than 4 nm. In some embodiments, the lateral width (or lateral thickness) of the insulative liner material is not more than 2 nm. For example, the discussed techniques allow scaling of the insulative liner material to thicknesses that are not dependent on the need for multiple lithography operations.

In some embodiments, the lateral width (or lateral thickness) of the insulative liner material is not more than 30% of the width (e.g., diameter) of the metal via. For example, the metal via may have a width of about 40 nm. In some embodiments, the lateral width (or lateral thickness) of the insulative liner material is not more than 25% of the width (e.g., diameter) of the metal via. In some embodiments, the lateral width (or lateral thickness) of the insulative liner material is not more than 20% of the width (e.g., diameter) of the metal via. In some embodiments, the lateral width (or lateral thickness) of the insulative liner material is not more than 10% of the width (e.g., diameter) of the metal via. In some embodiments, the lateral width (or lateral thickness) of the insulative liner material is not more than 5% of the width (e.g., diameter) of the metal via.

Processing continues at operation 111, where frontside metallization layers are fabricated over the transistor layer and the metal via. Such processing may be performed using any suitable technique or techniques. In some embodiments, the frontside metallization layers may be formed over (and selectively coupled to) gate electrodes or gate contacts, source contacts, drain contacts, and deep metal vias (e.g., bridge vias). For example, the frontside metallization layers may contact such components in accordance with the circuitry of the integrated circuit being fabricated. The frontside metallization layers may be formed using any suitable technique or techniques such as dual damascene techniques, single damascene techniques, subtractive metallization patterning techniques, or the like. For example, interconnectivity, signal routing, power-delivery, and the like may be provided by the frontside metallization layers. As used herein, the term metallization layer indicates a layer including metal interconnections or wires that provide electrical routing and may include metal lines, metal vias, and metal components embedded in insulative material. The term metallization indicates a metal feature or component (e.g., metal line, via, or other component) of the metallization layer.

Processing continues at operation 112, where the workpiece is mounted to a carrier, the deep backside via is exposed, and backside metallization is formed opposite the frontside metallization with respect to the transistor layer. In some embodiments, the partially fabricated workpiece is mounted, by its frontside, to a carrier such as a carrier wafer, and the discussed bridge via is exposed through the backside of the substrate of the workpiece. The workpiece may be mounted to the carrier using any suitable technique or techniques such as application of an adhesive film between the workpiece and carrier. The bridge via is then exposed using any suitable technique or techniques such as backside substrate removal processing including backside grind, backside etch, or the like to thin the substrate.

The backside metallization layers are then fabricated over the exposed bridge via (and opposite the transistor layer with respect to the frontside metallization layers). In some embodiments, one of the backside metallization layers contacts the bridge via. The backside metallization layers may be formed using any suitable technique or techniques such as dual damascene techniques, single damascene techniques, subtractive metallization patterning techniques, or the like. For example, interconnectivity, signal routing, power-delivery, and the like may be provided by the backside metallization layers.

Processing continues at operation 113, where the carrier is removed using any suitable technique or techniques such as delamination, UV curing, or the like, and where continued processing is performed as is known in the art. Such processing may include dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

Discussion now turns to FIGS. 2-13, which are cross-sectional views of transistor structures evolving as methods 100 are practiced to form a bridge via adjacent to transistor gate electrodes.

FIG. 2 illustrates a cross-sectional side view of a transistor structure 200 including a number of sets 208 of semiconductor structures 207 each formed over a substrate 201. Each set 208 of semiconductor structures 207 corresponds to a functional transistor that may be implemented in an integrated circuit. Semiconductor structures 207 may also be characterized as semiconductor ribbons (inclusive of nano-ribbons, nano-sheets, and nano-wires). In the context of FIG. 2, the cross-sectional side view is taken at a gate cut. In FIGS. 2-13, a bridge via is formed in the gate track of transistor structure 200 (e.g., between or interspersed among gate electrodes and contacts). With reference to FIG. 14, a transistor structure 1400 is illustrated at a source/drain cut (e.g., into or out of the page of FIG. 2) and FIGS. 14-26 illustrate a bridge via formed in the source/drain track of transistor structure 1400 (e.g., between or interspersed among source/drain structures and contacts). It will be appreciated the discussed operations may be performed separately to form bridge vias in differing integrated circuit embodiments or in concert in the same integrated circuit embodiments.

Returning to FIG. 2, substrate 201 may include any suitable material or materials. For example, substrate 201 may be a substrate substantially aligned along a predetermined crystal orientation (e.g., <100>, <111>, <110>, or the like). In some embodiments, substrate 201 is a semiconductor material such as monocrystalline silicon (Si), germanium (Ge), silicon germanium (SiGe), III-V materials (e.g., gallium arsenide (GaAs)), a silicon carbide (SiC), a sapphire (Al₂O₃), or any combination thereof. In some embodiments, substrate 201 is silicon having a <111> crystal orientation. Semiconductor structures 207 may be any suitable semiconductor material or materials such as silicon, germanium, silicon germanium, a III-V material, a TMD material, or others. In some embodiments, semiconductor structures 207 are formed from a fin, leaving subfin portions 204, which may be under a dielectric layer 202 and embedded in isolation material 203.

As shown, a channel region 205 of each of semiconductor structures 207 is surrounded by a gate dielectric 206 on each of semiconductor structures 207. As used herein, the term channel region indicates a region or portion of a material or structure that is manipulated by a gate to operate a transistor. Notably, the transistor need not be in operation for a region to be a channel region. Gate dielectric 206 may be silicon oxide, aluminum oxide, or a high-k dielectric, such as hafnium oxide. For example, gate dielectric 206 may include elements such as hafnium, silicon, oxygen, titanium, tantalum, lanthanum, aluminum, zirconium, barium, strontium, yttrium, lead, scandium, niobium, or zinc.

As shown, a gate structure includes gate dielectric 206 and gate electrode 209. Gate electrodes 209 may include any suitable work function metal for transistor gate control such as tantalum, titanium, aluminum, ruthenium, or alloys of such materials and a fill metal such as tungsten. With reference to FIG. 14, semiconductor structures 207 extend between a source 1402 (or source structure) and a drain (or drain structure) that is into or out of the page with respect to sources 1402. As discussed, the cross-section of FIG. 14 is into or out of the page with respect to the cross-section of FIG. 2. Returning to FIG. 2, gate dielectric 206 and gate electrode 209 are adjacent channel regions 205 of semiconductor structures 207 to form a three-terminal transistor device. Although illustrated herein with respect to a gate-all-around (GAA) field effect transistor (FET) architectures, the structures and techniques may be deployed with respect to FinFET transistor architectures, tri- or dual-gate transistor architectures, or planar transistor architectures. Over gate electrode 209, transistor structure 200 may include a dielectric layer 210. Dielectric layer 210 may be any suitable material such as silicon nitride (e.g., including silicon and nitrogen). In some embodiments, dielectric layer is substantially pure or pure silicon nitride. In some embodiments, dielectric layer 210 is the same material as gate dielectric 206.

As discussed with respect to operation 102, a stack of layers 221 is formed over the remainder of transistor structure 200. As shown, stack of layers 221 may include an etch stop layer 211, a dielectric layer 212 on etch stop layer 211, a hardmask layer 213 on dielectric layer 212, and a dielectric layer 214 on hardmask layer 213. In some embodiments, etch stop layer 211 is an aluminum oxide etch stop layer (e.g., substantially pure or pure aluminum oxide). In some embodiments, dielectric layer 212 is a silicon oxide layer (e.g., substantially pure or pure silicon oxide). In some embodiments, hardmask layer 213 is a silicon nitride hardmask layer (e.g., substantially pure or pure silicon nitride). In some embodiments, dielectric layer 214 is a silicon oxide layer (e.g., substantially pure or pure silicon oxide). Other material options may be used. Each layer of stack of layers 221 may be formed using any suitable technique or techniques such as CVD, PECVD, ALD, etc.

Etch stop layer 211, dielectric layer 212, hardmask layer 213, and dielectric layer 214 may have any suitable thicknesses (e.g., in the z-dimension). In some embodiments, etch stop layer 211 has a thickness in the range of about 1 to 3 nm. In some embodiments, dielectric layer 212 has a thickness in the range of about 3 to 7 nm. In some embodiments, hardmask layer 213 has a thickness in the range of about 12 to 25 nm. In some embodiments, dielectric layer 214 has a thickness in the range of about 3 to 7 nm.

FIG. 3 illustrates a cross-sectional side view of a transistor structure 300 similar to transistor structure 200 after the formation of an opening 301 in dielectric layer 212, hardmask layer 213, and dielectric layer 214 to form a patterned dielectric layer 312, a patterned hardmask layer 313, and a patterned dielectric layer 314, as discussed with respect to operation 103. Notably, opening 301 has a cross sectional shape (e.g., circular) that matches a desired via opening shape to be transferred to the underlying layers. Opening 301 may be formed using any suitable technique or techniques. In some embodiments, a resist layer is formed on dielectric layer 214, and the resist layer is patterned using lithography techniques to form an opening therein. The opening is then transferred via hardmask etch techniques to the underlying dielectric layer 212, hardmask layer 213, and dielectric layer 214 to form patterned dielectric layer 312, patterned hardmask layer 313, and patterned dielectric layer 314.

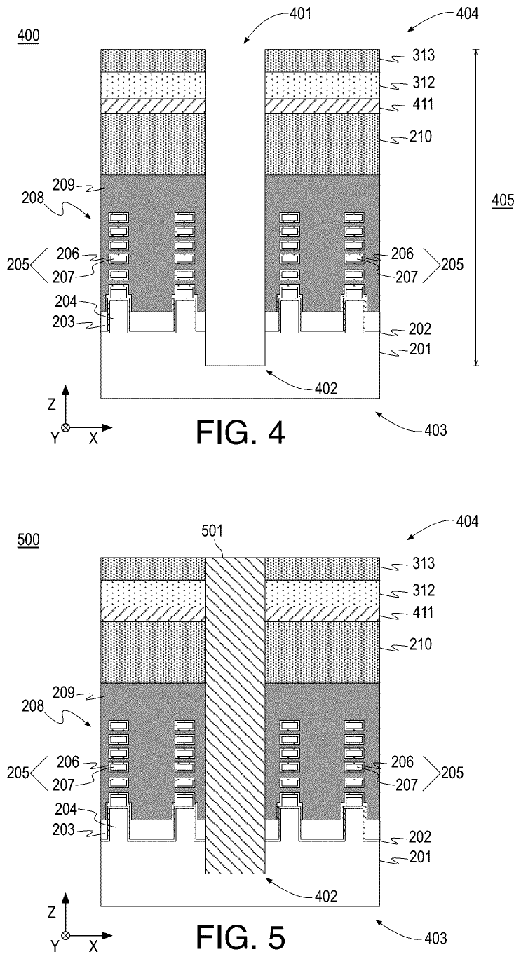

FIG. 4 illustrates a cross-sectional side view of a transistor structure 400 similar to transistor structure 300 after removal of an exposed portion of etch stop layer 211 to form patterned etch stop layer 411 and after a deep etch to form a deep via opening 401, as discussed with respect to operation 104. In some embodiments, the exposed portion of etch stop layer 211 is removed using a DHF etch. In some embodiments, the remaining underlying layers (including portions of gate electrode 209, isolation material 203, dielectric layer 202, and substrate 201) are patterned using a timed anisotropic etch that stops at a vertical position 402 that may be accessed via a backside 403 of transistor structure 400, which is opposite a frontside 404 of transistor structure 400.

For example, deep via opening 401 extends 405 vertically from an opening at frontside 404 to vertical position 402 within substrate 201, which will later be accessed via backside 403. As used herein the term frontside of a transistor structure indicates the side (or the direction of the side) being built up during front end of line (FEOL) processing of transistor structure 400, which is the processing performed on or over the received substrate 201, in accordance with the accepted use of frontside (e.g., a positive z-direction). The backside is then opposite the frontside and is the side opposite the buildup direction (e.g., a negative z-direction). As discussed below, a metal via in deep via opening 401 will be contacted from backside 403. As shown, in some embodiments, the etch processing removes an entirety of patterned dielectric layer 314 and a portion of a thickness of patterned hardmask layer 313.

FIG. 5 illustrates a cross-sectional side view of a transistor structure 500 similar to transistor structure 400 after deposition and planarization of a hardmask material 501, as discussed with respect to operation 105. As shown, hardmask material 501 plugs or fills deep via opening 401, and extends from frontside 404 to vertical position 402 within substrate 201. Hardmask material 501 may be a material having etch selectively with respect to patterned hardmask layer 313, patterned dielectric layer 312, and patterned etch stop layer 411. Hardmask material 501 may be deposited and planarized as discussed above. In some embodiments, hardmask material 501 is a carbon hardmask material such as an amorphous carbon material.

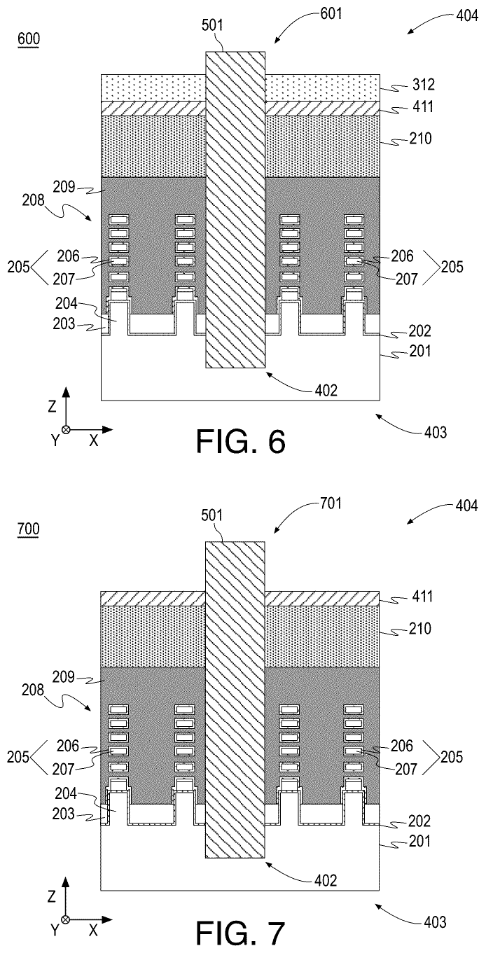

FIG. 6 illustrates a cross-sectional side view of a transistor structure 600 similar to transistor structure 500 after removal of patterned hardmask layer 313, as discussed with respect to operation 106. Patterned hardmask layer 313 may be removed using any suitable technique or techniques such as anisotropic etch techniques. For example, patterned hardmask layer 313 may be removed by an anisotropic silicon oxide etch. As shown, removal of patterned hardmask layer 313 leaves a protrusion 601 of hardmask material 501 extending vertically above patterned dielectric layer 312.

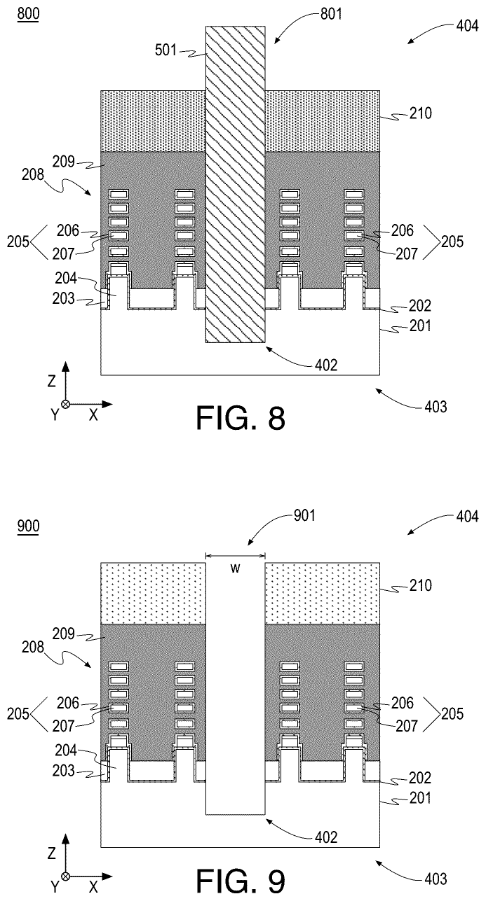

FIG. 7 illustrates a cross-sectional side view of a transistor structure 700 similar to transistor structure 600 after removal of patterned dielectric layer 312, as discussed with respect to operation 107. FIG. 8 illustrates a cross-sectional side view of a transistor structure 800 similar to transistor structure 700 after removal of patterned etch stop layer 411, also as discussed with respect to operation 104. As shown in FIG. 7, the oxide etch (e.g., an anisotropic oxide etch) leaves a protrusion 701 of hardmask material 501 extending vertically above patterned dielectric patterned etch stop layer 411. As shown in FIG. 8, the etch stop layer etch (e.g., a wet etch of aluminum oxide) also leaves a protrusion 801 of hardmask material 501 extending vertically above dielectric layer 210.

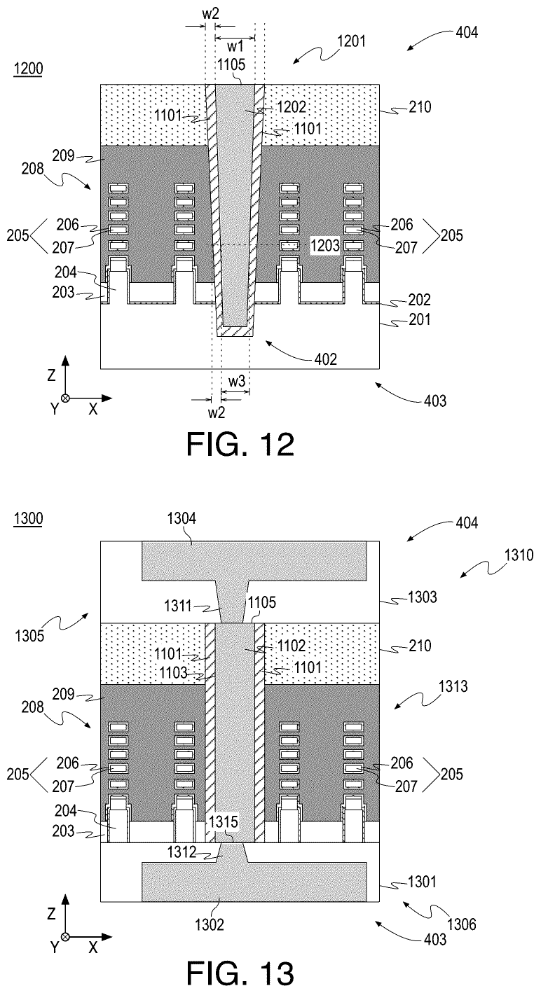

FIG. 9 illustrates a cross-sectional side view of a transistor structure 900 similar to transistor structure 800 after removal of hardmask material 501, as discussed with respect to operation 108. Removal of hardmask material 501 exposes opening 901 from frontside 404 to vertical position 402, as discussed above. Hardmask material 501 may be removed using any suitable technique or techniques such as ashing techniques. It is noted that opening 901 has a lateral width w (e.g., diameter) that is to accommodate an eventual insulative liner width (or lateral thickness) and metal via width (e.g., diameter). For example, lateral width w may be the sum of the metal via diameter and twice the insulative liner lateral thickness. The techniques discussed herein advantageously allow for a much greater metal via diameter to insulative liner lateral thickness ratio (e.g., 20 or more) as well as a greatly reduced insulative liner lateral thickness (e.g., 5 nm or less). In some embodiments, opening 901 may have a taper such a that the lateral width of opening 901 reduces in the negative z-direction as discussed with respect to FIG. 12 herein below.

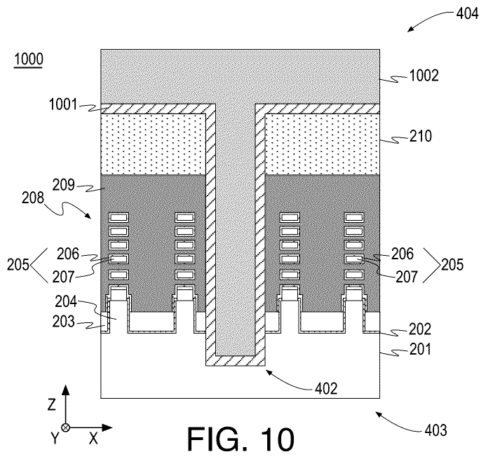

FIG. 10 illustrates a cross-sectional side view of a transistor structure 1000 similar to transistor structure 900 after deposition of insulative liner layer 1001 and deposition of bulk via metal 1002, as discussed with respect to operation 109. Insulative liner layer 1001 may be deposited using CVD, ALD, or other deposition techniques. In some embodiments, the insulative liner material is silicon nitride (e.g., includes silicon and nitrogen). In some embodiments, the insulative liner material is substantially pure or pure silicon nitride. In some embodiments, the insulative liner is a multi-layer stack of materials. In some embodiments, the insulative liner material is a continuous monolithic material. Bulk via metal 1002 may be formed using any suitable technique or techniques such as low pressure chemical vapor deposition (LPCVD), plating techniques, or others. Bulk via metal 1002 may be any suitable metal. In some embodiments, bulk via metal 1002 is or includes tungsten. However other metals may be deployed such as copper, aluminum, or others.

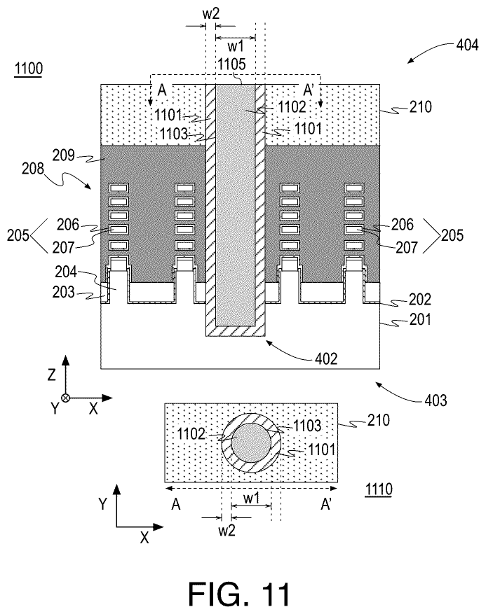

FIG. 11 illustrates a cross-sectional side view of a transistor structure 1100 similar to transistor structure 1000 after planarization to remove bulk metal and insulative liner material from regions outside of opening 901, as discussed with respect to operation 110. As shown, the planarization processing provides a metal via 1102 and an insulative liner layer 1101 on sidewalls of the opening (not labeled) and on a sidewall 1103 of metal via 1102. That is, insulative liner layer 1101 laterally surrounds metal via 1102 and is between metal via 1102 and other components of transistor structure 1100. For example, insulative liner layer 1101 may be on any other component of transistor structure 1100 such as gate electrode 209, or a source contact or a drain contact as discussed further herein below. Insulative liner layer 1101 provides electrical isolation of metal via 1102 from the other components of the transistor. As discussed, insulative liner layer 1101 may be advantageously thin, in particular, relative to the size (e.g., width) of metal via 1102.

FIG. 11 also illustrates, in insert 1110, a top-down view of transistor structure 1100. As shown, transistor structure 1100 includes metal via 1102 and insulative liner layer 1101 on sidewall 1103 of metal via 1102, and between metal via 1102 and the various components of transistor structure 1100. In some embodiments, insulative liner layer 1101 is a continuous monolithic material in contact with metal via 1102 and a component of transistor structure 1100. As shown, metal via 1102 has a first width w1 (e.g., diameter) adjacent an upper surface 1105 of metal via 1102. Insulative liner layer 1101 has a second width w2 (e.g., width of an annulus) adjacent upper surface 1105. For example, first width w1 and second width w2 are at the same vertical position. The discussed processing allows for second width w2 to be greatly reduced. In some embodiments, second width w2 is not more than half of first width w1. In some embodiments, second width w2 is not more than 30% of first width w1. In some embodiments, second width w2 is not more than 25% of first width w1. In some embodiments, second width w2 is not more than 20% of first width w1. In some embodiments, second width w2 is not more than 100% of first width w1. In some embodiments, second width w2 is not more than 5% of first width w1.

In some embodiments, the lateral width (or lateral thickness) w2 of insulative liner layer 1101 is less than 12 nm. In some embodiments, the lateral width (or lateral thickness) w2 of insulative liner layer 1101 is less than 10 nm. In some embodiments, the lateral width (or lateral thickness) w2 of insulative liner layer 1101 is less than 8 nm. In some embodiments, the lateral width (or lateral thickness) w2 of insulative liner layer 1101 is less than 5 nm. In some embodiments, the lateral width (or lateral thickness) w2 of insulative liner layer 1101 is less than 4 nm. In some embodiments, the lateral width (or lateral thickness) w2 of insulative liner layer 1101 is less than 2 nm. The first lateral width w1 may be any suitable width (e.g., diameter) such as a width in the range of 10 to 25 nm, a width in the range of 20 to 40 nm, a width in the range of 30 to 50 nm, etc.

Furthermore, the second lateral width may be substantially constant around metal via 1102. In some embodiments, the second lateral width does not vary by more than 5% at any two positions around metal via 1102 (e.g., (w2,1−w2,2)/w2,1≤5%, where w2,1 is the lateral width of insulative liner layer 1101 at a first position and w2,2 is the lateral width of insulative liner layer 1101 at a second position). In some embodiments, the second lateral width does not vary by more than 2% at any two positions around metal via 1102. In some embodiments, the second lateral width does not vary by more than 1% at any two positions around metal via 1102. For example, the two positions may be opposite metal via 1102 from one another (e.g., in line in the x-y plane and extending through a centerline of metal via 1102. In some embodiments, a second width w2 on a first lateral side of metal via 1102 and a second width w2 on a second lateral side of metal via opposite the first lateral side that is within 5% of the second width. In some embodiments, a centerline of metal via 1102 (in the z-dimension) and a centerline of an annuls of insulative liner layer 1101 (in the z-dimension) are at the same location such that they are within 2 nm of one another.

FIG. 12 illustrates a cross-sectional side view of a transistor structure 1200 having a metal via 1202 with a tapered profile 1201. For example, the width (e.g., diameter) of metal via 1202 may reduce or get smaller moving from upper surface 1105 toward vertical position 402 (e.g., moving in a negative z-direction) due to an etch profile generated while forming deep via opening 401 (refer to FIG. 4). In some embodiments, metal via 1202 has tapered profile 1201 (e.g., a taper), such that metal via 1202 has a width w3 (e.g., reduced diameter) at a position 1203 below upper surface 1105. In some embodiments, width is less than the width w1, and insulative liner layer 1101 has a matching width w2 at position 1203 and at or immediately adjacent upper surface 1105.

FIG. 13 illustrates a cross-sectional side view of a transistor structure 1300 similar to transistor structure 1100 after formation of frontside metallization 1305, mounting to a carrier, exposure of metal via 1102 from backside 403, and formation of backside metallization 1306, as discussed with respect to operations 111 and 112. For example, frontside metallization 1305 may be fabricated using techniques discussed above and includes metallization features 1304, 1311, any of which may contact metal via 1102 from frontside 404. As shown, metallization features 1304, 1311 are embedded in dielectric material 1303. After formation of frontside metallization 1305, the workpiece is attached to a carrier, a portion of substrate 201 is removed and backside metallization 1306 is fabricated. Backside metallization 1306 may be fabricated using techniques discussed above and includes metallization features 1302, 1312, any of which may contact metal via 1102 from backside 403. As shown, metallization features 1302, 1312 may be embedded in dielectric material 1301.

In some examples, package level interconnects (not shown) are provided on or over backside 403 as bumps over a passivation layer, as bond pads, solder bumps, etc. Frontside metallization 1305 may include any number of metallization layers such as 10 to 15 metal layers with one being illustrated for the sake of clarity. Similarly, backside metallization 1306 may include any number of metallization layers such as three, four, or more.

For example, an integrated circuit die 1310 may include one or more transistors 1313, such that one or more of transistors 1313 each includes semiconductor structures 207 extending between a source 1402 (e.g., source structure) and a drain (e.g., drain structure; refer to FIG. 14), and gate electrode 209 (or gate structure) adjacent channel regions 205 of semiconductor structures 207. Transistor structure 1300 also includes metal via 1102 extending from frontside metallization 1305 over transistors 1313 to backside metallization 1306 below transistors. The terms above and below are used in accordance with their accepted orientation in the art such that above (or over) is in the direction toward frontside 404 (e.g., in the positive z-direction) and below (or under) is in the direction toward backside 403 (e.g., in the negative z-direction). Metal via 1102 has first width w1 adjacent upper surface 1105 of the metal via (refer to FIG. 11). Notably, upper surface 1105 is in contact with metallization feature 1311 of frontside metallization 1305. Furthermore, bottom surface 1315 (as exposed via backside 403) is in contact with metallization feature 1312 of backside metallization 1306. Transistor structure 1300 includes insulative liner layer 1101 on sidewall 1103 of metal via 1102, and between metal via 1102 and one or more components of transistor 1313, such that insulative liner layer 1101 has second width w2 adjacent upper surface 1105 that is not more than one fifth of the first width w1 (or any other fraction or percentage discussed herein).

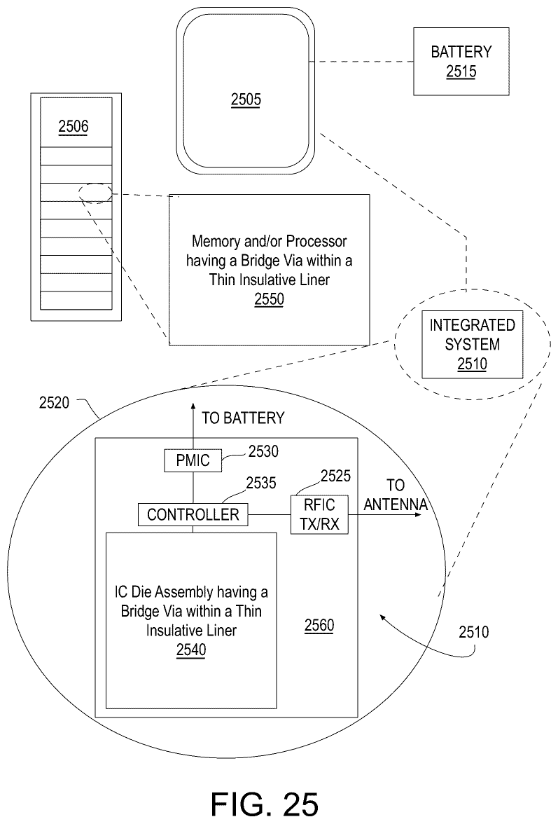

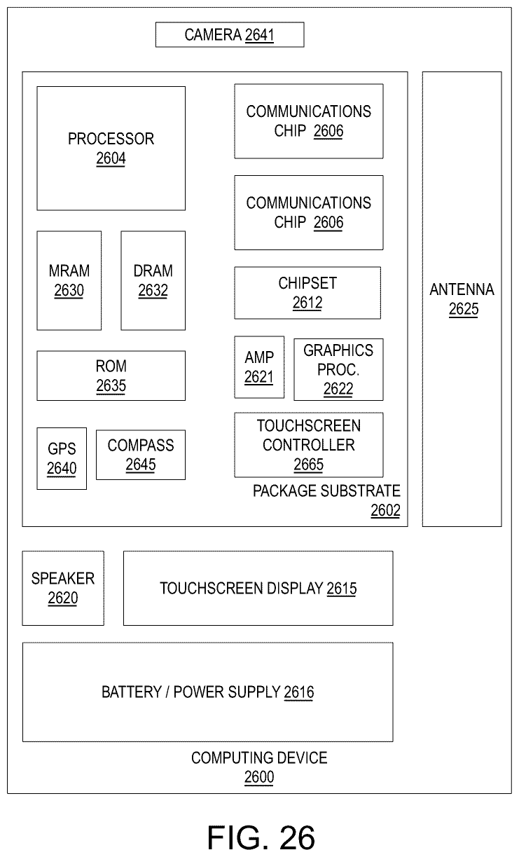

In some embodiments, transistor structure 1300 is deployed in monolithic integrated circuit (IC) die 1310 including a transistor (e.g., a three-terminal transistor device), the transistor including any of the above discussed components and characteristics. For example, the transistor may include one or more semiconductor structures extending between a source structure and a drain structure, and a gate structure adjacent to one or more channel regions of the one or more semiconductor structures, the IC die may further include a via extending from a frontside metallization over the transistor to a backside metallization below the transistor, such that the via has a first width adjacent the frontside metallization. The IC die may further include an insulative liner layer on a sidewall of the via, and between the via and a component of the transistor, such that the insulative liner layer has a second width adjacent the first width that is not more than one fifth of the first width. The A power supply or battery may be coupled to the IC die as shown with respect to FIGS. 25 and 26 herein below.

Discussion now turns to FIGS. 14-24, which are cross-sectional views of transistor structures evolving as methods 100 are practiced to form a bridge via adjacent to source and drain structures and source and drain contacts.

FIG. 14 illustrates a cross-sectional side view of a transistor structure 1400 including sources 1402 and source contacts 1405 each formed over a substrate 201. As discussed, sources 1402 and source contacts 1405 are into or out of the page with respect to the view of FIG. 2. Furthermore, drains and drain contacts are into or out of the page with respect to the view of FIG. 14. For example, semiconductor structures 207 (refer to FIG. 2) extend between sources 1402 and the drains into the page of FIG. 14. That is, in the context of FIG. 14, the cross-sectional side view is taken at a source cut, which is a similar view to a drain cut. Although illustrated with respect to a source cut, the discussed components may be deployed with respect to a drain cut. For example, in FIGS. 14-24, references to sources and drains may be used interchangeably. In FIGS. 14-24, a bridge via is formed in a source or drain track of transistor structure 1400 (e.g., between or interspersed among source structures and source contacts or drain structures and drain contacts).

Returning to FIG. 14, sources 1402 and corresponding drains (not shown) may be a semiconductor material grown epitaxially from exposed portions of semiconductor structures 207. The source and drain semiconductor material may include faceting and epitaxial growth structures and characteristics, and the source and drain semiconductor may include any suitable material or materials for the conductivity type of the transistor being deployed. In some embodiments, for NMOS transistors, the source and drain semiconductor is epitaxial silicon doped with n-type dopants inclusive of phosphorous, arsenic, antimony, or others. In some embodiments, for PMOS transistors, the source and drain semiconductor is epitaxial silicon germanium doped with p-type dopants inclusive of boron, aluminum, gallium, indium, or others. Source contacts 1405 and corresponding drain contacts (not shown) may include any suitable conductive contact materials such as tungsten, copper, cobalt, aluminum, or the like. As shown, sources 1402 and corresponding drains (not shown) may be formed within multilayer stack 1404 including a dielectric 1401, and may be embedded in dielectric material 1406.

As shown, a channel region 205 of each of semiconductor structures 207 is surrounded by a gate dielectric 206 on each of semiconductor structures 207. As used herein, the term channel region indicates a region or portion of a material or structure that is manipulated by a gate to operate a transistor. Notably, the transistor need not be in operation for a region to be a channel region. Gate dielectric 206 may be silicon oxide, aluminum oxide, or a high-k dielectric, such as hafnium oxide. For example, gate dielectric 206 may include elements such as hafnium, silicon, oxygen, titanium, tantalum, lanthanum, aluminum, zirconium, barium, strontium, yttrium, lead, scandium, niobium, or zinc.

As discussed with respect to operation 102, a stack of layers 221 is formed over the remainder of transistor structure 1400. Stack of layers 221 may include etch stop layer 211, dielectric layer 212 on etch stop layer 211, hardmask layer 213 on dielectric layer 212, and dielectric layer 214 on hardmask layer 213. Such layers may have any characteristics, and may be formed using any techniques, discussed with respect to FIG. 2 and elsewhere herein. In some embodiments, etch stop layer 211 is an aluminum oxide etch stop layer, dielectric layer 212 is a silicon oxide layer, hardmask layer 213 is a silicon nitride hardmask layer, and dielectric layer 214 is a silicon oxide layer.

FIG. 15 illustrates a cross-sectional side view of a transistor structure 1500 similar to transistor structure 1400 after the formation of an opening 1501 in dielectric layer 212, hardmask layer 213, and dielectric layer 214 to form a patterned dielectric layer 1512, a patterned hardmask layer 1513, and a patterned dielectric layer 1514, as discussed with respect to operation 103. Opening 1501 has a cross sectional shape (e.g., circular) that matches a desired via opening shape to be transferred to the underlying layers. Opening 1501 may be formed by forming a resist layer on dielectric layer 214, patterning the resist layer, and transferring a patterned opening in the resist layer via hardmask etch techniques to the underlying stack of materials to form patterned dielectric layer 1512, patterned hardmask layer 1513, and patterned dielectric layer 1514.

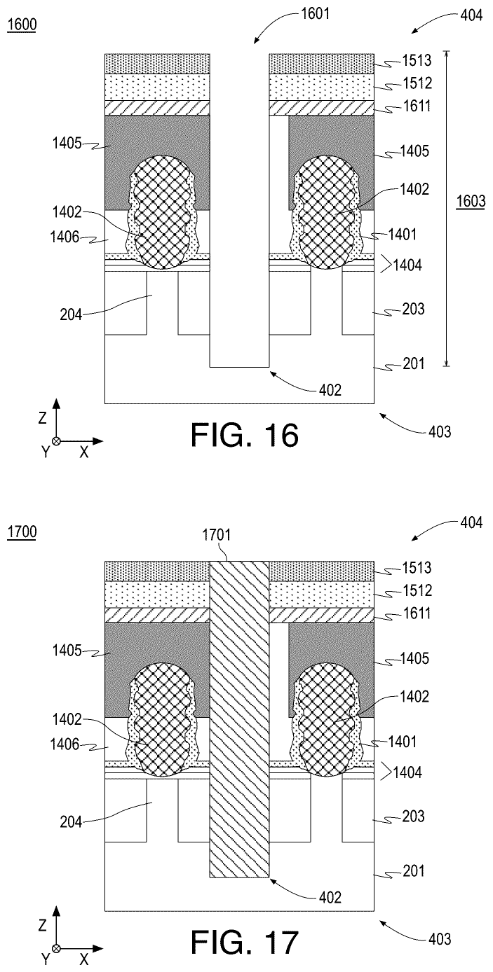

FIG. 16 illustrates a cross-sectional side view of a transistor structure 1600 similar to transistor structure 1500 after removal of an exposed portion of etch stop layer 211 to form patterned etch stop layer 1611 and after a deep etch to form a deep via opening 1601, as discussed with respect to operation 104. The exposed portion of etch stop layer 211 may be removed using a DHF etch and the remaining underlying layers (including portions of source contacts 1405, drain contacts, dielectric material 1406, multilayer stack 1404, and optionally sources, and drains) may be patterned using a timed anisotropic etch that stops at vertical position 402 that may be accessed via a backside 403, as discussed above. As shown, deep via opening 1601 extends 1603 vertically from an opening at frontside 404 to vertical position 402 within substrate 201, which will later be accessed via backside 403. In some embodiments, the etch processing removes an entirety of patterned dielectric layer 1514 and a portion of a thickness of patterned hardmask layer 1513.

FIG. 17 illustrates a cross-sectional side view of a transistor structure 1700 similar to transistor structure 1600 after deposition and planarization of a hardmask material 1701, as discussed with respect to operation 105. Hardmask material 1701 plugs or fills deep via opening 1601, and extends from frontside 404 to vertical position 402 within substrate 201. Hardmask material 1701 may be a material having etch selectively with respect to patterned hardmask layer 1513, patterned dielectric layer 1512, and patterned etch stop layer 1611. Hardmask material 1701 may be deposited and planarized using any suitable technique or techniques. In some embodiments, hardmask material 1701 is a carbon hardmask material such as an amorphous carbon material.

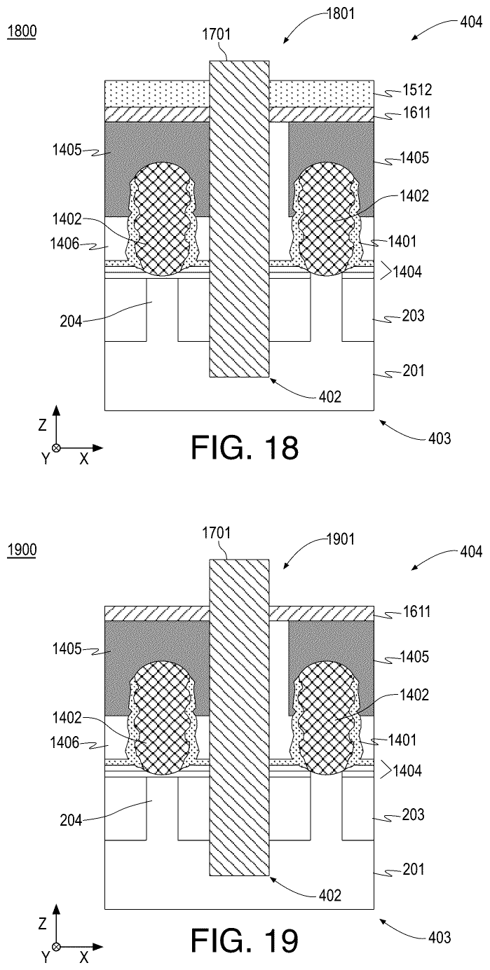

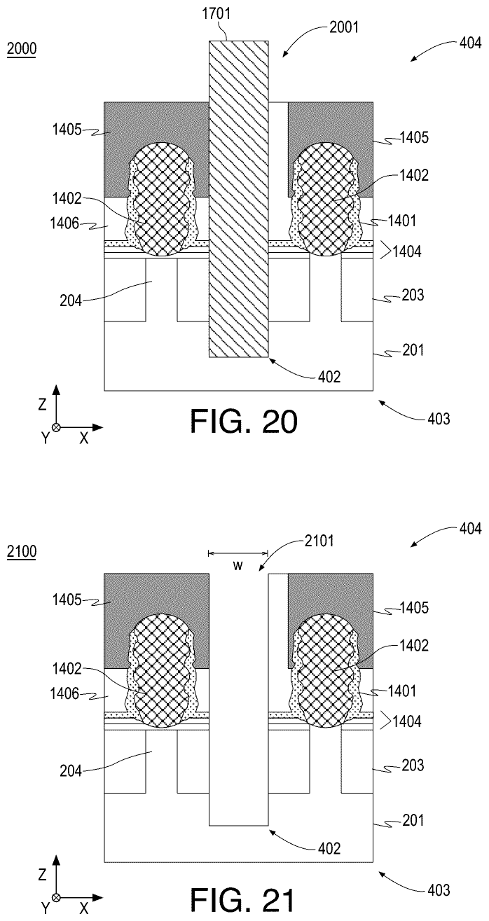

FIG. 18 illustrates a cross-sectional side view of a transistor structure 1800 similar to transistor structure 1700 after removal of patterned hardmask layer 1513, as discussed with respect to operation 106. Patterned hardmask layer 313 may be removed using anisotropic etch techniques such as an anisotropic silicon oxide etch. As shown, removal of patterned hardmask layer 1513 leaves a protrusion 1801 of hardmask material 501 extending vertically above patterned dielectric layer 1512. FIG. 19 illustrates a cross-sectional side view of a transistor structure 1900 similar to transistor structure 1800 after removal of patterned dielectric layer 1512, as discussed with respect to operation 107. FIG. 20 illustrates a cross-sectional side view of a transistor structure 2000 similar to transistor structure 1900 after removal of patterned etch stop layer 1611, also as discussed with respect to operation 104. As shown in FIG. 19, the oxide etch (e.g., an anisotropic oxide etch) leaves a protrusion 1901 of hardmask material 1701 extending vertically above patterned dielectric patterned etch stop layer 1611. As shown in FIG. 20, the etch stop layer etch (e.g., a wet etch of aluminum oxide) also leaves a protrusion 2001 of hardmask material 1701 extending vertically above source contacts 1405 and dielectric material 1406.

FIG. 21 illustrates a cross-sectional side view of a transistor structure 2100 similar to transistor structure 2000 after removal of hardmask material 1701, as discussed with respect to operation 108. Removal of hardmask material 1701 exposes opening 2101 from frontside 404 to vertical position 402. Hardmask material 1701 may be removed using ashing techniques, for example. As shown, opening 2101 has a lateral width w (e.g., diameter) that is to accommodate an eventual insulative liner width (or lateral thickness) and metal via width (e.g., diameter), which may have any characteristics discussed above. In some embodiments, opening 2101 may have a taper as discussed with respect to FIG. 12.

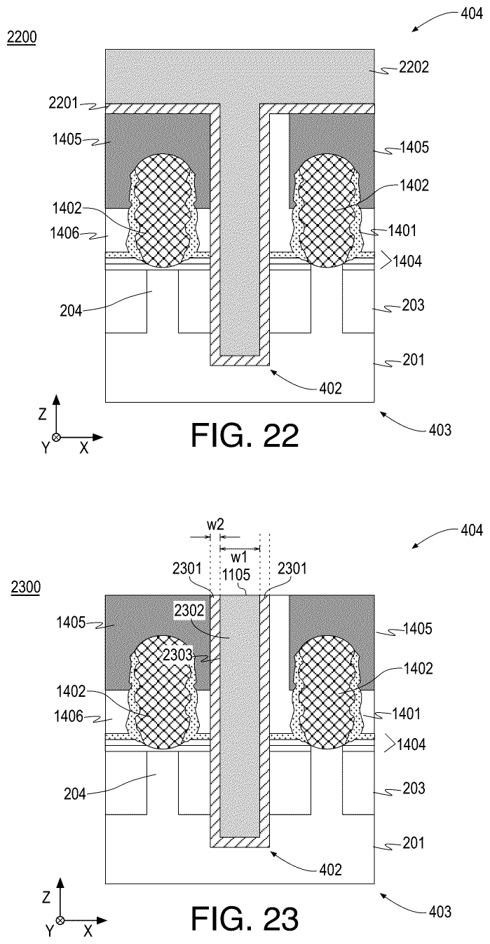

FIG. 22 illustrates a cross-sectional side view of a transistor structure 2200 similar to transistor structure 2100 after deposition of insulative liner layer 2201 and deposition of bulk via metal 2202, as discussed with respect to operation 109. Insulative liner layer 2201 may be deposited using CVD, ALD, or other deposition techniques, and insulative liner layer 2201 maybe any suitable insulative material such as silicon nitride. The insulative liner material may be substantially pure or pure or it may be a multi-layer stack of materials. In some embodiments, the insulative liner material is a continuous monolithic material. Bulk via metal 2202 may be formed using any suitable technique or techniques such as low pressure chemical vapor deposition (LPCVD), plating techniques, or others, and bulk via metal 1002 may be any suitable metal such as tungsten, copper, aluminum, or others.

FIG. 23 illustrates a cross-sectional side view of a transistor structure 2300 similar to transistor structure 2200 after planarization to remove bulk metal and insulative liner material from regions outside of opening 1601, as discussed with respect to operation 110. The planarization processing provides a metal via 2302 akin to metal via 1102 and an insulative liner layer 2301 akin to insulative liner layer 1101 on sidewalls of the opening (not labeled) and on a sidewall 2303 of metal via 2302. Metal via 2302 may have any characteristics discussed with respect to metal via 1102 and insulative liner layer 2301 may have any characteristics discussed with respect to insulative liner layer 1101.

As shown, insulative liner layer 2301 laterally surrounds metal via 2302 and is between metal via 2302 and other components of transistor structure 2300. For example, insulative liner layer 2301 may be on any other component of transistor structure 2300 such as source contacts 1405 or drain contacts, sources 1402 or drains, dielectric material 1406, or others. Insulative liner layer 2301 provides electrical isolation of metal via 2302 from the other components of the transistor. As discussed, insulative liner layer 2301 may be advantageously thin, in particular, relative to the size (e.g., width) of metal via 2302. As discussed, metal via 2302 may have any characteristics discussed with respect to metal via 1102 and insulative liner layer 2301 may have any characteristics discussed with respect to insulative liner layer 1101 inclusive of dimensions, materials, taper, and so on. Such features will not be repeated for the sake of brevity.

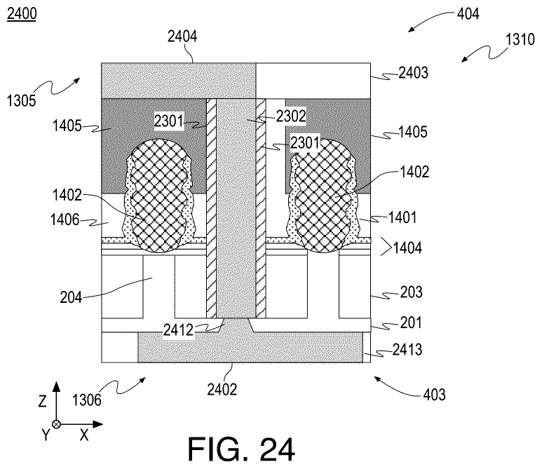

FIG. 24 illustrates a cross-sectional side view of a transistor structure 2400 similar to transistor structure 2300 after formation of frontside metallization 1305, mounting to a carrier, exposure of metal via 2302 from backside 403, and formation of backside metallization 1306, as discussed with respect to operations 111 and 112. For example, frontside metallization 1305 may be fabricated using techniques discussed above and includes metallization feature 2404 which may contact metal via 2302 from frontside 404. As shown, metallization feature 2404 may be embedded in dielectric material 2403. After formation of frontside metallization 1305, the workpiece is attached to a carrier, a portion of substrate 201 is removed and backside metallization 1306 is fabricated. Backside metallization 1306 includes metallization features 2402, 2412, any of which may contact metal via 2302 from backside 403. Metallization features 2402, 2412 may be embedded in dielectric material 2413.

In some examples, package level interconnects (not shown) are provided on or over backside 403 as bumps over a passivation layer, as bond pads, solder bumps, etc. For example, integrated circuit die 1310 may include transistor structure 2400 having any characteristics discussed with respect to FIGS. 14-24.

FIG. 25 illustrates exemplary systems employing transistor structures having a bridge via within a thin insulative liner, in accordance with some embodiments. The system may be a mobile computing platform 2505 and/or a data server machine 2506, for example. Either may employ a monolithic IC die, for example, having a bridge via within a thin insulative liner as described elsewhere herein. Server machine 2506 may be any commercial server, for example including any number of high-performance computing platforms disposed within a rack and networked together for electronic data processing, which in the exemplary embodiment includes an IC die assembly 2550 with a field effect transistor and a bridge via within a thin insulative liner spanning the field effect transistor between frontside and backside metallization layers as described elsewhere herein. Mobile computing platform 2505 may be any portable device configured for each of electronic data display, electronic data processing, wireless electronic data transmission, or the like. For example, mobile computing platform 2505 may be any of a tablet, a smart phone, a laptop computer, etc., and may include a display screen (e.g., a capacitive, inductive, resistive, or optical touchscreen), a chip-level or package-level integrated system 2510, and a battery/power supply 2515. Although illustrated with respect to mobile computing platform 2505, in other examples, chip-level or package-level integrated system 2510 and a battery/power supply 2515 may be implemented in a desktop computing platform, an automotive computing platform, an internet of things platform, or the like. As discussed below, in some examples, the disclosed systems may include a sub-system 2560 such as a system on a chip (SOC) or an integrated system of multiple ICs, which is illustrated with respect to mobile computing platform 2505.

Whether disposed within integrated system 2510 illustrated in expanded view 2520 or as a stand-alone packaged device within data server machine 2506, sub-system 2560 may include memory circuitry and/or processor circuitry 2540 (e.g., RAM, a microprocessor, a multi-core microprocessor, graphics processor, etc.), a power management integrated circuit (PMIC) 2530, a controller 2535, and a radio frequency integrated circuit (RFIC) 2525 (e.g., including a wideband RF transmitter and/or receiver (TX/RX)). As shown, one or more IC dice, such as memory circuitry and/or processor circuitry 2540 may be assembled and implemented such that one or more have a bridge via within a thin insulative liner as described herein. In some embodiments, RFIC 2525 includes a digital baseband and an analog front end module further comprising a power amplifier on a transmit path and a low noise amplifier on a receive path). Functionally, PMIC 2530 may perform battery power regulation, DC-to-DC conversion, etc., and so has an input coupled to battery/power supply 2515, and an output providing a current supply to other functional modules. As further illustrated in FIG. 25, in the exemplary embodiment, RFIC 2525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2540 may provide memory functionality for sub-system 2560, high level control, data processing and the like for sub-system 2560. In alternative implementations, each of the SOC modules may be integrated onto separate ICs coupled to a package substrate, interposer, or board.

FIG. 26 is a functional block diagram of an electronic computing device 2600, in accordance with some embodiments. For example, device 2600 may, via any suitable component therein, implement a field effect transistor and a bridge via within a thin insulative liner spanning the field effect transistor between frontside and backside metallization layers as discussed herein. For example, one or more IC dies of electronic computing device 2600 may deploy a GAA transistor and a bridge via within a thin insulative liner spanning the GAA such that the insulative liner is between the bridge via and other components of the GAA. Device 2600 further includes a motherboard or package substrate 2602 hosting a number of components, such as, but not limited to, a processor 2604 (e.g., an applications processor). Processor 2604 may be physically and/or electrically coupled to package substrate 2602. In some examples, processor 2604 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 2606 may also be physically and/or electrically coupled to the package substrate 2602. In further implementations, communication chips 2606 may be part of processor 2604. Depending on its applications, computing device 2600 may include other components that may or may not be physically and electrically coupled to package substrate 2602. These other components include, but are not limited to, volatile memory (e.g., DRAM 2632), non-volatile memory (e.g., ROM 2635), flash memory (e.g., NAND or NOR), magnetic memory (MRAM 2630), a graphics processor 2622, a digital signal processor, a crypto processor, a chipset 2612, an antenna 2625, touchscreen display 2615, touchscreen controller 2665, battery/power supply 2616, audio codec, video codec, power amplifier 2621, global positioning system (GPS) device 2640, compass 2645, accelerometer, gyroscope, speaker 2620, camera 2641, and mass storage device (such as hard disk drive, solid-state drive (SSD), compact disk (CD), digital versatile disk (DVD), and so forth, or the like.

Communication chips 2606 may enable wireless communications for the transfer of data to and from the computing device 2600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 2606 may implement any of a number of wireless standards or protocols, including, but not limited to, those described elsewhere herein. As discussed, computing device 2600 may include a plurality of communication chips 2606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 2616 may include any suitable power supply circuitry and, optionally, a battery source to provide power to components of electronic computing device 2600.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

The following pertains to exemplary embodiments.

In one or more first embodiments, an apparatus comprises a transistor comprising one or more semiconductor structures extending between a source structure and a drain structure, and a gate structure adjacent to one or more channel regions of the one or more semiconductor structures, a via extending from a frontside metallization over the transistor to a backside metallization below the transistor, wherein the via has a first width adjacent the frontside metallization, and an insulative liner layer on a sidewall of the via, wherein the insulative liner layer has a second width adjacent the first width that is not more than one fifth of the first width.

In one or more second embodiments, further to the first embodiments, the second width is not more than 10% of the first width.

In one or more third embodiments, further to the first or second embodiments, the second width is not more than 5 nm.

In one or more fourth embodiments, further to the first through third embodiments, the second width is on a first lateral side of the via and wherein the insulative liner layer has a third width on a second lateral side of the via opposite the first lateral side that is within 5% of the second width.

In one or more fifth embodiments, further to the first through fourth embodiments, the insulative liner layer is on a component of the transistor, the component of the transistor comprising one of a gate electrode of the gate structure, a source contact, or a drain contact.

In one or more sixth embodiments, further to the first through fifth embodiments, the via comprises a taper, the via has a third width at a position below the first width that is less than the first width, and the insulative liner layer has the second width at the position of the third width.

In one or more seventh embodiments, further to the first through sixth embodiments, the insulative liner layer comprises silicon and nitrogen.

In one or more eighth embodiments, further to the first through seventh embodiments, the insulative liner layer comprises a continuous monolithic material in contact with the via and the component of the transistor.

In one or more ninth embodiments, a system comprises an integrated circuit (IC) die according to any of the apparatuses of the first through eighth embodiments, and a power supply coupled to the IC die.

In one or more tenth embodiments, a system comprises an IC die comprising a transistor comprising one or more semiconductor structures extending between a source and a drain, and a gate adjacent to the semiconductor structures, a bridge via extending from a frontside metal over the transistor to a backside metal below the transistor, wherein the bridge via has a first width immediately adjacent the frontside metal, and an insulative liner on a sidewall of the bridge via, wherein the insulative liner has a second width adjacent the first width that is not more than one fifth of the first width, and a power supply coupled to the IC die.

In one or more eleventh embodiments, further to the tenth embodiments, the first width is not less than 25 nm and the second width is not more than 5 nm.

In one or more twelfth embodiments, further to the tenth or eleventh embodiments, the second width is not more than 2 nm.

In one or more thirteenth embodiments, further to the tenth through twelfth embodiments, the second width is on a first lateral side of the bridge via and wherein the insulative liner has a third width on a second lateral side of the bridge via opposite the first lateral side that is within 5% of the second width.

In one or more fourteenth embodiments, further to the tenth through thirteenth embodiments, the bridge via comprises a taper, the bridge via has a third width at a second position below the position, the third width is less than the first width, and the insulative liner layer has the first width at the second position.

In one or more fifteenth embodiments, further to the tenth through fourteenth embodiments, the insulative liner layer comprises silicon and nitrogen, wherein the insulative liner layer comprises a continuous monolithic material in contact with the bridge via and a component of the transistor, the component of the transistor comprising one of a gate electrode of the gate structure, a source contact, or a drain contact, and wherein the bridge via comprises tungsten.

In one or more sixteenth embodiments, a method comprises forming a material stack over a workpiece comprising a transistor structure, the material stack comprising an etch stop layer and one or more patterned layers comprising a pattern over the etch stop layer, etching a deep via opening across a depth of the transistor structure by transferring the pattern from the one or more patterned layers, filling the deep via opening with a hardmask material, removing the one or more patterned layers and the etch stop layer, removing the hardmask material to expose the deep via opening, forming an insulative liner on a sidewall of the deep via, and forming a metal via on the insulative liner within the deep via opening.

In one or more seventeenth embodiments, further to the sixteenth embodiments, the etch stop layer comprises aluminum and oxygen, and the hardmask material comprises carbon.

In one or more eighteenth embodiments, further to the sixteenth or seventeenth embodiments, the one or more patterned layers comprise at least one layer comprising silicon and nitrogen.

In one or more nineteenth embodiments, further to the sixteenth through eighteenth embodiments, the one or more patterned layers comprise at least one layer comprising silicon and oxygen.

In one or more twentieth embodiments, further to the sixteenth through nineteenth embodiments, the metal via has a first width and the insulative liner has a lateral thickness at the first width that is not more than half of the first width.

In one or more twenty-first embodiments, further to the sixteenth through twentieth embodiments, the lateral thickness is not more than 20% of the first width.

It will be recognized that the invention is not limited to the embodiments so described but can be practiced with modification and alteration without departing from the scope of the appended claims. For example, the above embodiments may include specific combination of features. However, the above embodiments are not limited in this regard, and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a transistor comprising one or more semiconductor structures extending between a source structure and a drain structure, and a gate structure adjacent to one or more channel regions of the one or more semiconductor structures;
a via extending from a frontside metallization over the transistor to a backside metallization below the transistor, wherein the via has a first width adjacent the frontside metallization; and
an insulative liner layer on a sidewall of the via, wherein the insulative liner layer has a second width adjacent the first width that is not more than one fifth of the first width.

2. The apparatus of claim 1, wherein the second width is not more than 10% of the first width.

3. The apparatus of claim 2, wherein the second width is not more than 5 nm.

4. The apparatus of claim 1, wherein the second width is on a first lateral side of the via and wherein the insulative liner layer has a third width on a second lateral side of the via opposite the first lateral side that is within 5% of the second width.

5. The apparatus of claim 1, wherein the insulative liner layer is on a component of the transistor, the component of the transistor comprising one of a gate electrode of the gate structure, a source contact, or a drain contact.

6. The apparatus of claim 1, wherein the via comprises a taper, the via has a third width at a position below the first width that is less than the first width, and the insulative liner layer has the second width at the position of the third width.

7. The apparatus of claim 1, wherein the insulative liner layer comprises silicon and nitrogen.

8. The apparatus of claim 7, wherein the insulative liner layer comprises a continuous monolithic material in contact with the via and a component of the transistor.

9. A system, comprising:
an integrated circuit (IC) die comprising:
a transistor comprising one or more semiconductor structures extending between a source and a drain, and a gate adjacent to the semiconductor structures;
a bridge via extending from a frontside metal over the transistor to a backside metal below the transistor, wherein the bridge via has a first width immediately adjacent the frontside metal; and
an insulative liner on a sidewall of the bridge via, wherein the insulative liner has a second width adjacent the first width that is not more than one fifth of the first width; and
a power supply coupled to the IC die.

10. The system of claim 9, wherein the first width is not less than 25 nm and the second width is not more than 5 nm.

11. The system of claim 10, wherein the second width is not more than 2 nm.

12. The system of claim 9, wherein the second width is on a first lateral side of the bridge via and wherein the insulative liner has a third width on a second lateral side of the bridge via opposite the first lateral side that is within 5% of the second width.

13. The system of claim 9, wherein the bridge via comprises a taper, the bridge via has a third width at a second position below the position, the third width is less than the first width, and the insulative liner has the first width at the second position.

14. The system of claim 9, wherein the insulative liner comprises silicon and nitrogen, wherein the insulative liner comprises a continuous monolithic material in contact with the bridge via and a component of the transistor, the component of the transistor comprising one of a gate electrode of the gate, a source contact, or a drain contact, and wherein the bridge via comprises tungsten.

15. A method, comprising:
forming a material stack over a workpiece comprising a transistor structure, the material stack comprising an etch stop layer and one or more patterned layers comprising a pattern over the etch stop layer;
etching a deep via opening across a depth of the transistor structure by transferring the pattern from the one or more patterned layers;
filling the deep via opening with a hardmask material;
removing the one or more patterned layers and the etch stop layer;
removing the hardmask material to expose the deep via opening;
forming an insulative liner on a sidewall of the deep via; and
forming a metal via on the insulative liner within the deep via opening.

16. The method of claim 15, wherein the etch stop layer comprises aluminum and oxygen, and the hardmask material comprises carbon.

17. The method of claim 16, wherein the one or more patterned layers comprise at least one layer comprising silicon and nitrogen.

18. The method of claim 17, wherein the one or more patterned layers comprise at least one layer comprising silicon and oxygen.

19. The method of claim 15, wherein the metal via has a first width and the insulative liner has a lateral thickness at the first width that is not more than half of the first width.

20. The method of claim 19, wherein the lateral thickness is not more than 20% of the first width.
